(19) United States
(12) Patent Application Publication
(10) Pub. No.: US 2008/0291061 A1
(43) Pub. Date: Nov. 27, 2008

(54) SYSTEM FOR DEVELOPMENT OF INPUT DEVICE

(75) Inventors: Lae-Hyun KIM, Seoul (KR); Se-Hyung PARK, Seoul (KR); Kang PARK, Seoul (KR)

Correspondence Address: SCULLY SCOTT MURPHY & PRESSER, PC, 400 GARDEN CITY PLAZA, SUITE 300, GARDEN CITY, NY, 11530, US

(73) Assignee: AGENCY FOR DEFENSE DEVELOPMENT, Daejeon (KR)

(21) Appl. No.: 12/123,562

(22) Filed: May 20, 2008

(30) Foreign Application Priority Data
May 25, 2007 (KR) 10-2007-0051087

(51) Int. Cl. H03K 17/94

(52) U.S. Cl. 341/35

(57) ABSTRACT

A system for development of an input device capable of implementing an input device of various shapes and functions by providing the same visual, haptic, and audible feedbacks as a product to be massively fabricated when the input device is designed. The system comprises: an input device for receiving a rotation input by a user, and generating tactile feedbacks corresponding to the rotation input; a display device for displaying a virtual input device having a designable appearance in an interworking manner in correspondence with the user's manipulation; and a controller for controlling the input device by being connected thereto so that the tactile feedbacks corresponding to the rotation input can be provided, and for controlling the display device so that the virtual input device can be displayed in correspondence with the user's manipulation.

### BACKGROUND OF THE INVENTION

1. Field of the Invention

The present invention relates to a system for development of an input device applicable to electronic equipment.

2. Description of the Background Art

Generally, electronic equipment being recently presented has a tendency to hide complicated functions therein, but to mount a delicate input device outside thereof instead of several input modules. In order to develop the input device of the electronic equipment, a prototype input device has to be firstly fabricated. (For precise) Precise fabrication of the physical prototype saves time and cost. However, a design for the electronic equipment is much corrected by many factors, thereby requiring much time and cost in developing the prototype input device.

To solve the problems, a virtual prototyping technique has been developed. The virtual prototyping technique indicates a technique for virtually analyzing and evaluating appearance and a function of a virtual prototype on a computer in a design step before fabricating a substantial product. For example, a prototype of an input device is virtually fabricated on a computer, and the prototype is displayed by interworking by controlling a mouse. Accordingly, development of the input device is facilitated.

However, according to the virtual prototyping technique, only visual information is displayed on only a computer monitor. Accordingly, haptic feedbacks implemented when a substantially fabricated input device is used can not be provided. Therefore, even if the virtual prototyping technique is used, many physical prototypes have to be fabricated to evaluate hands-on experience by the users.

Recently, electronic equipment having various functions and having a simple input device is required. In order to manipulate many functions of the electronic equipment without increasing complexity of the input device, it is effective to utilize a user's tactile feedbacks, that is, haptic feedbacks.

However, making physical prototypes to test psychophysical and emotional factors related to tactile feedback requires much time and costs. Furthermore, since the aforementioned virtual prototyping technique is not enough to develop the delicate input device, tactile feedback should be added to the traditional prototyping system.

### SUMMARY OF THE INVENTION

Therefore, it is an object of the present invention to provide a system for development of an input device capable of facilitating development of an input device by providing haptic feedbacks such as tactile feedbacks for a substantial product.

More concretely, it is an object of the present invention to provide a system for development of an input device capable of providing haptic feedbacks such as tactile feedbacks for a substantial input device at the time of a designing process, by overcoming shortcomings of a virtual prototyping technique and a substantial prototyping technique.

It is another object of the present invention to provide a system for development of an input device capable of co-locating between a viewed position and a manipulated position of an input device by co-locating a visual space and a tactile space. Accordingly, a cognitive mismatch is overcome, and a user's intuitive interface is provided.

To achieve these and other advantages and in accordance with the purpose of the present invention, as embodied and broadly described herein, there is provided a system for development of an input device, comprising: an input device for receiving a rotation input by a user, and generating tactile feedbacks corresponding to the rotation input; a display device for displaying a virtual input device having a designable appearance in an interworking manner in correspondence with the user's manipulation; and a controller for controlling the input device by being connected thereto so that the tactile feedbacks corresponding to the user's manipulation can be provided, and for controlling the display device so that the virtual input device can be displayed in correspondence with the user's manipulation.

To achieve these and other advantages and in accordance with the purpose of the present invention, as embodied and broadly described herein, there is also provided an input device for receiving an input by a user, comprising: a dial unit that is exchangeable; a sensor for detecting a rotation input of the dial unit; an actuator for generating pre-programmed tactile feedbacks corresponding to the rotation input detected by the sensor; a controller for controlling the tactile feedbacks to be generated from the actuator according to the input detected by the sensor; a body connected to the dial unit through a rotation shaft, for housing at least one of the sensor, the actuator, and the controller; and a base plate mounted below the body, and having a weight heavy enough to stably mount the input device on the ground.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a system for development of an input device according to the present invention;

FIG. 2 is a detailed exemplary view of the input device of FIG. 1;

FIG. 3 is a block diagram showing a configuration of the system of FIG. 1; and

FIG. 4 is an exemplary view of various haptic feedbacks implemented by the system for development of an input device according to the present invention.

### DETAILED DESCRIPTION OF THE INVENTION

Reference will now be made in detail to the preferred embodiments of the present invention, examples of which are illustrated in the accompanying drawings.

Hereinafter, a system for development of an input device according to the present invention will be explained in more detail with reference to the attached drawings.

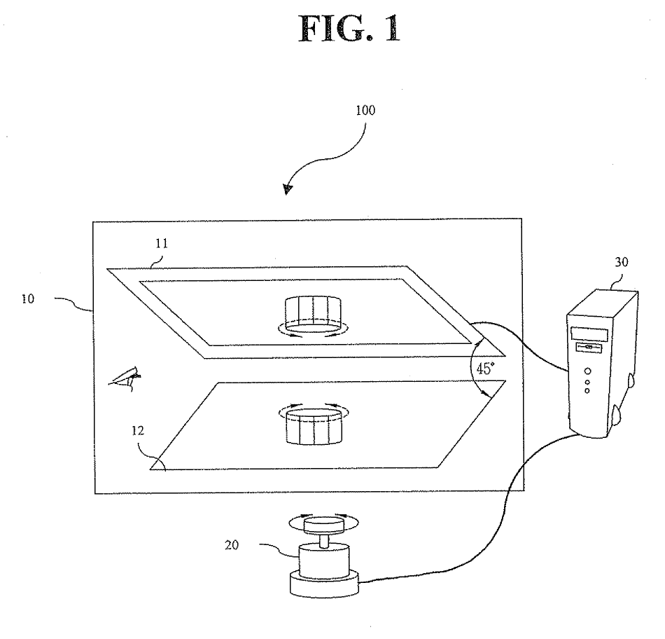

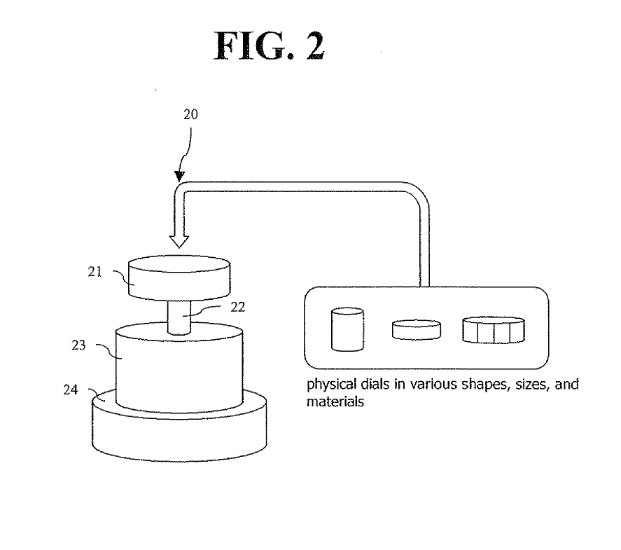

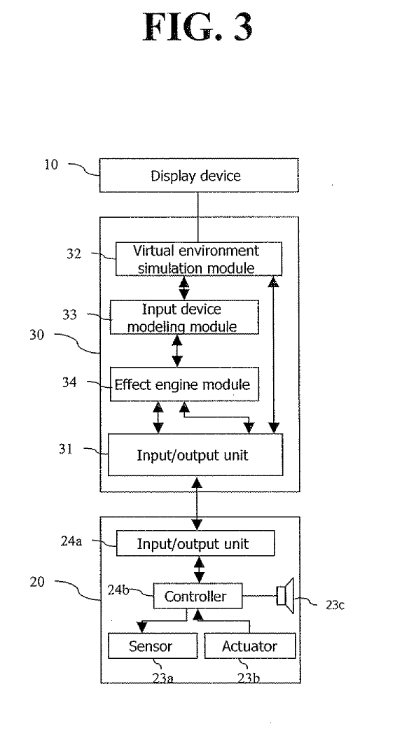

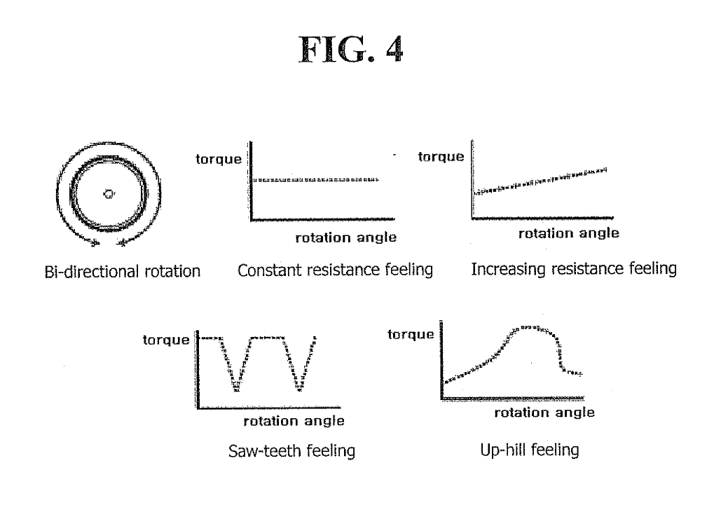

FIG. 1 is a system for development of an input device according to the present invention, FIG. 2 is a detailed exemplary view of the input device of FIG. 1, FIG. 3 is a block diagram showing a configuration of the system of FIG. 1, and FIG. 4 is an exemplary view of various haptic feedbacks implemented by the system for development of an input device according to the present invention.

Referring to FIG. 1, a system 100 for development of an input device comprises: an input device 20 (substantial input device) for generating pre-programmed tactile feedbacks, that is, haptic feedbacks when manipulated by a user; a display device 10 for displaying a virtual input device having a designed appearance and type in an interworking manner when the input device 20 is manipulated by the user; and a controller 30 for controlling haptic feedbacks of the input device 20 by receiving the user's input signal from the input device 20, and for displaying the virtual input device on the display device 10. The display device 10 includes a display unit 11 for displaying a virtual input device in an interworking manner when the input device 20 is manipulated by a user. The display unit 11 may be implemented as a CRT (Cathode-Ray Tube) display an LCD (Liquid Crystal Display), an OLED (Organic Light Emitting Diode), etc. The display unit 11 may display the virtual input device on two or three-dimensional planes.

The display device 10 may further comprise a half mirror 12 for reflecting a screen of the display unit 11. The half mirror 12 provides a visual effect that a voluminous virtual input device seems to exist below the half mirror 12. To this end, the half mirror 12 is disposed in parallel to the ground, and the display unit 11 is disposed with an angle of approximately 45° from the ground. Furthermore, a virtual input device that can be observed through the input device 20 and the half mirror 12 is aligned with the input device 20 and the half mirror 12, thereby spatially synchronizing visual and tactile feedbacks. That is, the virtual input device is viewed to a user by overlapping the input device 20. Accordingly, when the user manipulates the input device 20, the virtual input device visually observed at the same position is moved in cooperation with the input device 20.

The input device 20 may be implemented as a dial type (or a wheel, a jog shuttle), a ball type, a button type, or a slide type.

As shown in FIG. 2, when implemented as a dial type, the input device 20 may include a dial unit 21, a rotation shaft 22, a body 23, and a base plate 24.

As shown in FIG. 2, the dial unit 21 is mounted to the rotation shaft 22, and is configured to be fitted into the rotation shaft 22 with various sizes, shapes, and materials.

The body 23 includes therein a sensor 23a for detecting a rotated degree of the dial unit 21 by the rotation shaft 22, and an actuator 23b for providing haptic feedbacks. The body 23 may further include therein a speaker 23c for providing sound to a user.

The sensor 23a can detect at least one of a position variation and a rotated degree of the input device 20. That is, the sensor 23a can detect at least one of a motion variation, a rotation direction, a rotation angular variation, and a rotation angular velocity.

The actuator 23b may be implemented as a motor, a brake, or a combination therebetween. The actuator 23b provides haptic feedbacks such as a substantial dialing to a user by reproducing haptic effects according to a programming by the controller 30.

The base plate 24 includes a heavy material such as metal. When the dial unit 21 is rotated by a user, the base plate 24 prevents the input device 20 from entirely rotating and from being fluctuated in right and left directions. A vibration preventing member (not shown) for preventing vibration due to the actuator 23b from being transmitted to the bottom may be mounted below the base plate 24.

The base plate 24 includes therein an input/output unit 24a for transceiving signals, and a controller 24b for controlling the sensor 23a, the actuator 23b, and the speaker 23c. Here, the input/output unit 24a and the controller 24b may be included in the body 23.

The input/output unit 24a may be composed of electronic components for wire communications or infrared communications, or electronic components for wireless communications such as Bluetooth™, wireless USB, Zigbee, and UWB (Ultra Wideband). The input/output unit 24a transmits a position variation or a rotation variation detected by the sensor 23a to the controller 30. The input/output unit 24a also receives a signal for controlling the actuator 23b or the speaker 23c from the controller 30.

The controller 24b provides a position variation or a rotation variation detected through the sensor 23a to the input/output unit 24a after property processing it, so that the input/output unit 24a can transmit the position variation or the rotation variation to the controller 30, And, the controller 24b controls the actuator 23b and the speaker 23c according to control signals of the actuator 23b and the speaker 23c received through the input/output unit 24a.

As shown in FIG. 3, the controller 30 includes an input/output unit 31, a virtual environment simulation module 32, an input device modeling module 33, and an effect engine module 34. Here, the virtual environment simulation module 32, the input device modeling module 33, and the effect engine module 34 are implemented by software. However, the software may be implemented as hardware by being mounted in a memory and operated by a processor.

The input/output unit 31 is the same as the input/output unit 24a of the aforementioned input device 20, and thus its detailed explanation will be omitted.

For convenience, the input device modeling module 33 will be firstly explained. The input device modeling module 33 defines a type of an input device to be designed, for example, a dial type (or wheel, jog shuttle), or a ball type, or a button type. And, the input device modeling module 33 designs desired appearance (design) of the input device. The input device modeling module 33 performs a modeling for haptic feedbacks (frictional force, resistant force, momentum, rotation range, etc. relating to substantial haptic feedbacks of the input device) according to the defined type and appearance of the input device.

The effect engine module 34 generates tactile feedbacks, that is, haptic effects and sounds corresponding to a user's input by using information from the input device modeling module 33. That is, in order to generate various haptic feedbacks, the effect engine module 34 can control factors of the haptic feedbacks such as a torque, a rotation range, a rotation direction, a rotation velocity, a rotation acceleration, and a PID (Proportional, Integrate, Derivative) gain. For example, as shown in FIG. 4, various effects such as a bi-directional rotation, a constant torque, an increasing torque, a saw-teeth shaped torque, and a hill-shaped torque can be programmed according to functions and purposes. The effect engine module 34 converts the generated haptic feedbacks to control signals, and transmits them to the actuator 24b through the input/output units 31, 24a.

The effect engine module 34 can compensate differences between a programmed size of haptic feedbacks and a substantial size of haptic feedbacks transmitted to a user through the input device 20.

The virtual environment simulation module 32 displays a virtual input device on the display device 10 with consideration of physical characteristics such as a position variation and a rotation variation of the input device 20 manipulated by a user.

The system for development of an input device according to the present invention has the following effects.

First, the same visual, physical, and audible feedbacks as those of massively fabricated products are provided at the time of designing an input device. Accordingly, the input device of various shapes and functions can be conveniently evaluated.

Second, an optimum product can be rapidly fabricated by considering functions, convenience, and appearance of the input device, and preferences thereon according to a user's age and sex.

The foregoing embodiments and advantages are merely exemplary and are not to be construed as limiting the present invention. The present teachings can be readily applied to other types of apparatuses. This description is intended to be illustrative, and not to limit the scope of the claims. Many alternatives, modifications, and variations will be apparent to those skilled in the art. The features, structures, methods, and other characteristics of the exemplary embodiments described herein may be combined in various ways to obtain additional and/or alternative exemplary embodiments.

As the present features may be embodied in several forms without departing from the characteristics thereof, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are therefore intended to be embraced by the appended claims.

What is claimed is:

1. An input device, comprising:
a sensor for detecting at least one of a position variation input and a rotation input;
an actuator for generating tactile feedbacks corresponding to the at least one of the inputs detected by the sensor; and
a controller for controlling the tactile feedbacks to be generated from the actuator according to the at least one of the inputs detected by the sensor.

2. The input device of claim 1, further comprising a dial unit that is exchangeable and configured to receive the rotation input from a user.

3. The input device of claim 2, wherein the dial unit is pre-fabricated in various sizes, shapes, and materials, and is optionally exchangeable.

4. The input device of claim 1, wherein in order to generate the tactile feedbacks, the actuator generates a constant torque, or an increasing torque, or a decreasing torque, or a stair-shaped torque, or a saw-teeth shaped torque, or a hill-shaped torque.

5. The input device of claim 1, wherein the actuator generates the tactile feedbacks, thereby setting a rotation range, a rotation direction, a rotation velocity, and a rotation acceleration that can be inputted by a user.

6. The input device of claim 1, further comprising a speaker for outputting sound corresponding to the at least one of the inputs detected by the sensor.

7. The input device of claim 1, further comprising an input/output unit for transmitting the at least one of the inputs detected by the sensor to an external controller, and receiving, from the external controller, the tactile feedbacks corresponding to the at least one of the inputs detected by the sensor.

8. An input device for receiving an input by a user, comprising:
a dial unit that is exchangeable;
a sensor for detecting a rotation input of the dial unit;
an actuator for generating pre-programmed tactile feedbacks corresponding to the rotation input detected by the sensor;
a controller for controlling the tactile feedbacks to be generated from the actuator according to the rotation input detected by the sensor;
a body connected to the dial unit through a rotation shaft, for housing at least one of the sensor, the actuator, and the controller; and
a base plate mounted below the body, and having a weight heavy enough to stably mount the input device on the ground.

9. The input device of claim 8, wherein the dial unit is pre-fabricated in various sizes, shapes, and materials, and is optionally exchangeable.

10. The input device of claim 8, wherein the actuator generates the tactile feedbacks, thereby setting a rotation range, a rotation direction, a rotation velocity, and a rotation acceleration that can be inputted by a user.

11. A system for development of an input device, comprising:
an input device for receiving a rotation input by a user, and generating tactile feedbacks corresponding to the rotation input;
a display device for displaying a virtual input device having a designable appearance in an interworking manner in correspondence with the user's manipulation; and
a controller for controlling the input device by being connected thereto so that the tactile feedbacks corresponding to the rotation input can be provided, and for controlling the display device so that the virtual input device can be displayed in correspondence with the user's manipulation.

12. The system of claim 11, wherein the display device comprises:
a display unit for displaying the virtual input device; and
a half mirror disposed to have an alternate angle with the display unit, for voluminously providing the virtual input device displayed on the display unit to a user.

13. The system of claim 11, wherein the input device and the virtual input device are visually synchronized with each other by aligning a position of the display.

14. The system of claim 11, wherein the input device comprises:
a dial unit that is exchangeable and configured to receive the rotation input from the user;
a sensor for detecting the rotation input by the dial unit;
an actuator for generating the tactile feedbacks corresponding to the input detected by the sensor; and
a controller for controlling the tactile feedbacks generated from the actuator according to the input detected by the sensor.

15. The system of claim 14, wherein the dial unit is pre-fabricated in various sizes, shapes, and materials, and is optionally exchangeable.

16. The system of claim 11, wherein the input device sets a user's inputtable rotation range, a rotation direction, a rotation velocity, and a rotation acceleration by generating the tactile feedbacks.

17. The system of claim 11, wherein the controller comprises:
an input device modeling module for designing a type, appearance, and haptic feedbacks of the input device;
an effect engine module for generating signals to control the input device so that the haptic feedbacks controlled to correspond to designed haptic feedbacks and a rotation input by the user can be generated; and
a virtual environment simulation module for displaying the virtual input device with a designed type and appearance.
